(19) United States
(12) Patent Application Publication
(10) Pub. No.: US 2024/0008357 A1
(43) Pub. Date: Jan. 4, 2024

(54) LIGHT-EMITTING ELEMENT AND LIGHT-EMITTING DEVICE

(71) Applicant: SHARP KABUSHIKI KAISHA, Sakai City, Osaka (JP)

(72) Inventors: MANABU NIBOSHI, Sakai City, Osaka (JP); YUTO TSUKAMOTO, Sakai City, Osaka (JP); TOKIYOSHI UMEDA, Sakai City, Osaka (JP)

(73) Assignee: SHARP KABUSHIKI KAISHA, Sakai City, Osaka (JP)

(21) Appl. No.: 18/035,747

(22) PCT Filed: Nov. 12, 2020
(86) PCT No.: PCT/JP2020/042208

§ 371 Date: May 7, 2023

(51) Int. Cl. H10K 85/50

(52) U.S. Cl. CPC H10K 85/50; H10K 50/181

(57) ABSTRACT

A light-emitting element includes a first electrode, a second electrode, a light-emitting layer provided between the first electrode and the second electrode and including a material having a perovskite structure, and a blocking layer provided in at least one of a position between the first electrode and the light-emitting layer or a position between the second electrode and the light-emitting layer, and configured to suppress migration of charges from the light-emitting layer.

### TECHNICAL FIELD

The disclosure relates to a light-emitting element and a light-emitting device.

### BACKGROUND ART

PTL 1 proposes a light-emitting element including a light-emitting layer including a metal halide perovskite, and an electron transport layer including a 1,10 phenanthroline derivative having a substituent at one or both of 2- and 9-positions of a 1,10 phenanthroline skeleton. This configuration can suppress light emission quenching due to diffusion, into the light-emitting layer, of an alkali metal or an alkali earth metal used for electron injection.

### CITATION LIST

### Patent Literature

PTL 1: JP 2018-107129 A

### SUMMARY OF INVENTION

### Technical Problem

The light-emitting element disclosed in PTL 1 described above can improve luminous efficiency. However, in the light-emitting element disclosed in PTL 1, charges injected into the light-emitting layer cannot be sufficiently confined in the light-emitting layer, and thus there is a problem that a luminance lifetime is reduced.

An object of the disclosure is to provide a light-emitting element and a light-emitting device capable of improving a luminance lifetime.

### Solution to Problem

A light-emitting element according to an aspect of the disclosure includes a first electrode, a second electrode, a light-emitting layer provided between the first electrode and the second electrode and including a material having a perovskite structure, and a blocking layer provided in at least one of a position between the first electrode and the light-emitting layer or a position between the second electrode and the light-emitting layer, and configured to suppress migration of charges from the light-emitting layer.

Further, a light-emitting device according to an aspect of the disclosure includes a thin film transistor, and a light-emitting element electrically connected to the thin film transistor, and including a first electrode, a second electrode, a light-emitting layer provided between the first electrode and the second electrode and including a material having a perovskite structure, and a blocking layer provided in at least one of a position between the first electrode and the light-emitting layer or a position between the second electrode and the light-emitting layer, and configured to suppress migration of charges from the light-emitting layer.

### BRIEF DESCRIPTION OF DRAWINGS

FIG. 1 is a schematic cross-sectional view of a light-emitting device according to an embodiment of the disclosure.

FIG. 2 is a table showing a correspondence relationship between each layer constituting a light-emitting element included in the light-emitting device illustrated in FIG. 1, and a material forming each layer.

FIG. 3 is an energy diagram illustrating a relationship between a lowest unoccupied molecular orbital (LUMO) and a highest occupied molecular orbital (HOMO) in each layer of the light-emitting element according to the embodiment of the disclosure.

FIG. 4 is a diagram schematically illustrating an example of a path of light emitted from the light-emitting element included in the light-emitting device according to the embodiment of the disclosure.

FIG. 5 is a graph showing angle dependence related to a chromaticity shift between the light-emitting device according to the embodiment of the disclosure and a light-emitting device according to a first comparative example.

FIG. 6 is a schematic cross-sectional view of a light-emitting device according to a first modified example of the embodiment of the disclosure.

FIG. 7 is a table showing a correspondence relationship between each layer constituting a light-emitting element included in the light-emitting device illustrated in FIG. 6, and a material forming each layer.

FIG. 8 is an energy diagram illustrating a relationship between a lowest unoccupied molecular orbital (LUMO) and a highest occupied molecular orbital (HOMO) in each layer of the light-emitting element according to the first modified example of the embodiment of the disclosure.

FIG. 9 is a graph showing angle dependence related to a chromaticity shift between the light-emitting device according to the first modified example of the embodiment of the disclosure and the light-emitting device according to the first comparative example.

FIG. 10 is a table showing a correspondence relationship between each layer constituting a light-emitting element included in a light-emitting device according to a second modified example of the embodiment of the disclosure, and a material forming each layer.

FIG. 11 is a graph showing angle dependence related to a chromaticity shift among the light-emitting device according to the second modified example of the embodiment of the disclosure, the light-emitting device according to the first comparative example, and a light-emitting device according to a second comparative example.

FIG. 12 is a graph showing angle dependence related to luminance between the light-emitting device according to the second modified example of the embodiment of the disclosure and the light-emitting device according to the second comparative example.

### DESCRIPTION OF EMBODIMENTS

With reference to the drawings, embodiments of the disclosure will be described below. Note that, in each drawing, similar configurations are denoted by the same reference sign, and descriptions thereof are omitted.

### EMBODIMENTS

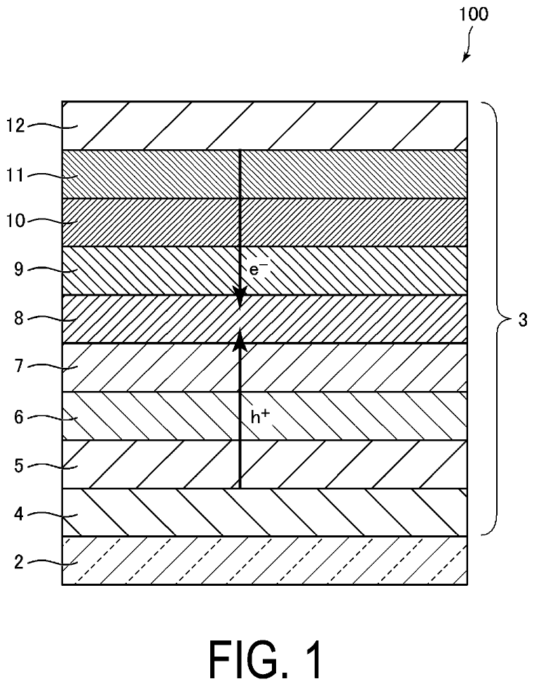

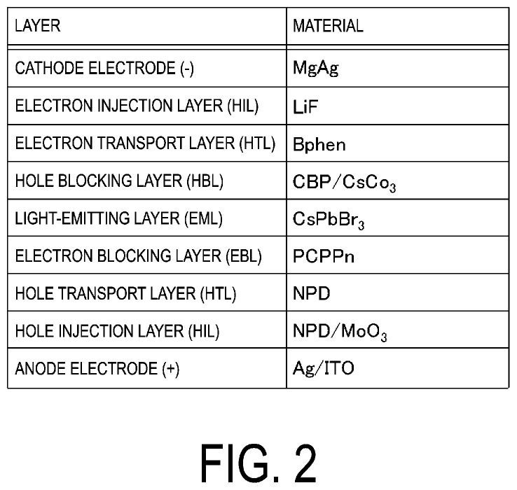

A configuration of a light-emitting device 100 according to the embodiment will be described with reference to FIGS. 1 and 2. FIG. 1 is a schematic cross-sectional view of the light-emitting device 100 according to the embodiment of the disclosure. In FIG. 1, a direction from an array substrate 2 of the light-emitting device 100 toward a light-emitting element 3 may be described as an “upward direction”, and an opposite direction may be described as a “downward direction”. FIG. 2 is a table showing a correspondence relationship between each layer constituting the light-emitting element 3 included in the light-emitting device 100 illustrated in FIG. 1, and a material forming each layer.

The light-emitting device 100 is a device that can be used for a display of a television, a smartphone, or the like, for example. As illustrated in FIG. 1, the light-emitting device 100 includes the array substrate 2 and the light-emitting element 3. The array substrate 2 is a glass substrate on which a thin film transistor (TFT) (not illustrated) for driving the light-emitting element 3 is formed. In the light-emitting device 100, each layer of the light-emitting element 3 is layered on the array substrate 2, and the TFT of the array substrate 2 and the light-emitting element 3 are electrically connected to each other.

The light-emitting element 3 includes an anode electrode 4 (first electrode), a hole injection layer 5, a hole transport layer 6, an electron blocking layer 7, a light-emitting layer 8, a hole blocking layer 9, an electron transport layer 10, an electron injection layer 11, and a cathode electrode 12 (second electrode). The light-emitting element 3 can be formed by layering, on the array substrate 2, the anode electrode 4, the hole injection layer 5, the hole transport layer 6, the electron blocking layer 7, the light-emitting layer 8, the hole blocking layer 9, the electron transport layer 10, the electron injection layer 11, and the cathode electrode 12 in this order from the bottom.

### Anode Electrode

The anode electrode 4 formed on the array substrate 2 and is electrically connected to the TFT provided on the array substrate 2. As shown in FIG. 2, the anode electrode 4 can be formed by layering, for example, Ag functioning as a reflective layer and having high light reflectivity and a transparent conductive film of ITO functioning as a transparent electrode and having optical transparency. The anode electrode 4 is formed on the array substrate 2 by using, for example, sputtering or vapor deposition as follows.

First, a reflective layer (e.g., Ag) is layered on the array substrate 2 by sputtering. A thickness of the reflective layer film-formed on the array substrate 2 can be, for example, 100 nm. Subsequently, a transparent electrode (ITO) is continuously layered. A thickness of the transparent electrode layered herein can be, for example, 20 nm. The layered body of Ag/ITO formed in such a manner is processed into a desired pattern by, for example, photolithography to form the anode electrode 4.

Note that the anode electrode 4 is formed of the layered body of Ag/ITO, which is not limited thereto. For example, the reflective layer may be metal including Al, Cu, Au, or the like instead of Ag. The transparent electrode may be a transparent conductive film of IZO, ZnO, AZO, BZO, or the like instead of ITO.

### Hole Injection Layer and Hole Transport Layer

The hole injection layer 5 allows holes to be injected from the anode electrode 4. The hole transport layer 6 transports, to the light-emitting layer 8 via the electron blocking layer 7 described later, the holes injected from the anode electrode 4 into the hole injection layer 5. The hole injection layer 5 and the hole transport layer 6 are formed on the anode electrode 4 and are electrically connected to the anode electrode 4.

As shown in FIG. 2, the hole injection layer 5 is formed on the anode electrode 4 by co-evaporating diphenylnaphthyldiamine (NPD) and MoO₃. As shown in FIG. 2, the hole transport layer 6 is formed on the hole injection layer 5 by performing vapor deposition on NPD.

Specifically, first, the following pretreatment is performed before the hole injection layer 5 and the hole transport layer 6 are formed. In other words, a surface of the anode electrode 4 formed as described above is washed with pure water and baked at 120° C. for an hour in a circulation type oven in an N₂ atmosphere for dehydration. Subsequently, plasma surface treatment using a non-polymerizable gas (for example, Ar) or the like is performed on the anode electrode 4.

On the anode electrode 4 subjected to the pretreatment in such a manner, diphenylnaphthyldiamine (NPD) being a hole transport material and MoO₃ being a hole injection material are co-evaporated in vacuum to form the hole injection layer 5. Note that NPD and MoO₃ are deposited at a ratio of NPD:MoO₃=1.00:0.15. A film thickness of the hole injection layer 5 formed at this time can be, for example, 90 nm. Subsequently, only NPD is deposited to form the hole transport layer 6. A film thickness of the hole transport layer 6 can be, for example, 20 nm. In this way, the hole injection layer 5 and the hole transport layer 6 can be formed on the anode electrode 4.

### Electron Blocking Layer

The electron blocking layer 7 suppresses migration of electrons (charges) such that the electrons do not leak from the adjacent light-emitting layer 8. The electron blocking layer 7 is formed on the hole transport layer 6 and is electrically connected to the anode electrode 4. As shown in FIG. 2, the electron blocking layer 7 can be formed of, for example, 3-[4-(9-phenanthryl)-phenyl]-9-phenyl-9H-carbazole (PCPPn).

In other words, PCPPn is vacuum vapor deposited on the hole transport layer 6 to form the electron blocking layer 7. A film thickness of the electron blocking layer 7 can be, for example, 10 nm. However, the electron blocking layer 7 may be damaged by a solvent or the like used in a step of forming the light-emitting layer 8 subsequently formed on the electron blocking layer 7. Thus, the electron blocking layer 7 may be formed thicker by 10 nm in consideration of the influence of such damage. Alternatively, the electron blocking layer 7 may be formed by co-evaporating PCPPn and an oxide film such as an SiOₓ film or a TiOₓ film on the hole transport layer 6. Alternatively, the electron blocking layer 7 may be formed by co-evaporating PCPPn and a p-type semiconductor material such as MoO₃ or V₂O₅ on the hole transport layer 6. By forming the electron blocking layer 7 in such a manner, the electron blocking layer 7 can be an organic layer having a hole injection property.

Further, a film thickness of the electron blocking layer 7 may be appropriately adjusted such that an optical distance in which light emitted from the light-emitting layer 8 of the light-emitting element 3 moves has a layered structure of the light-emitting element 3 that satisfies a condition (1/2×λ×n (n is an odd number)) described below.

### Light-Emitting Layer

The light-emitting layer 8 is provided between the anode electrode 4 and the cathode electrode 12, more specifically, between the electron blocking layer 7 and the hole blocking layer 9. The light-emitting layer 8 includes a metal halide perovskite material as a material having a perovskite structure. The metal halide perovskite material may be a composite material of an organic material and an inorganic material or a material formed of an inorganic material. Examples of the metal halide perovskite material include a lead metal halide compound represented by MPbX₃ (M;Cs, MeNH₃, X;I, Br, Cl).

The metal halide perovskite material has a narrow full width at half maximum (FWHM) of a peak wavelength of electroluminescence (EL) and can emit light having relatively deep chromaticity as compared with a phosphorescent material used in a light-emitting layer of a conventionally known OLED.

In the light-emitting element 3 according to the embodiment, the light-emitting layer 8 is formed of, for example, CsPbBr₃ as shown in FIG. 2. In other words, an HBr solvent solution is prepared by adding PbBr₂ serving as a precursor of the light-emitting layer 8 to a solution including HBr as a solvent. Furthermore, an aqueous solution of CsBr is prepared and dripped to the HBr solvent solution described above to obtain CsPbBr₃.

The obtained CsPbBr₃ is filtered, washed with ethanol, and vacuum-degassed at a temperature of 60° C. for 12 hours to obtain a powdery raw material. The powdered CsPbBr₃ and CH₃NH₃Br are added to a DMSO solvent and mixed, and the mixture is applied onto the electron blocking layer 7. Note that a combination ratio of CsPbBr₃ and CH₃NH₃Br is adjusted to 1:1. After the application, it is dried at a temperature of 90° C. for 30 minutes in an N₂ atmosphere to form the light-emitting layer 8. A film thickness of the light-emitting layer 8 can be, for example, 30 to 120 nm.

Note that the light-emitting layer 8 is formed by the application as described above, but the formation method is not limited thereto. Other methods may be used as long as the light-emitting layer 8 can be formed with an appropriate film thickness by using a metal halide perovskite material.

### Hole Blocking Layer

The hole blocking layer 9 suppresses migration of holes (charges) such that the holes do not leak from the adjacent light-emitting layer 8. The hole blocking layer 9 is formed on the light-emitting layer 8. The hole blocking layer 9 is formed on the light-emitting layer 8 by using, for example, vapor deposition or the like as follows.

In other words, after the light-emitting layer 8 is formed as described above, 4,4′-bis (N-carbazolyl)-1,1′-biphenyl (CBP) and CsCO₃ are co-evaporated in vacuum on the light-emitting layer 8 to form the hole blocking layer 9. A film thickness of the hole blocking layer 9 can be, for example, 10 nm.

The hole blocking layer 9 may include ZnO or TiO₂ instead of CsCO₃ described above. In other words, the hole blocking layer 9 may include, in addition to CBP, an n-type semiconductor material including at least one type selected from a group of CsCO₃, ZnO, SiO, and TiO₂.

### Electron Injection Layer and Electron Transport Layer

The electron injection layer 11 allows electrons to be injected from the cathode electrode 12. The electron transport layer 10 transports, to the light-emitting layer 8 via the hole blocking layer 9, the electrons injected from the cathode electrode 12 into the electron injection layer 11. The electron injection layer 11 and the hole transport layer 6 are formed on the hole blocking layer 9 and are electrically connected to the cathode electrode 12. The electron injection layer 11 and the electron transport layer 10 are formed on the hole blocking layer 9 by using, for example, vapor deposition or the like as follows.

In other words, 4,7-diphenyl-1,10-phenanthroline (Bphen) is deposited in vacuum on the hole blocking layer 9 to form the electron transport layer 10. A film thickness of the electron transport layer 10 can be, for example, 20 nm. LiF is further deposited in vacuum on the electron transport layer 10 formed in such a manner to form the electron injection layer 11. A film thickness of the electron injection layer 11 can be, for example, 0.5 nm.

### Cathode Electrode

The cathode electrode 12 is provided on the electron injection layer 11 and is electrically connected to the electron injection layer 11, the electron transport layer 10, and the hole blocking layer 9. The cathode electrode 12 can be formed of, for example, a metal thinned to a degree having optical transparency, or a transparent material. In the light-emitting element 3 according to the embodiment of the disclosure, the cathode electrode 12 is formed of, for example, an alloy of Mg and Ag as shown in FIG. 2.

In other words, MgAg that is an alloy including Mg and Ag at a ratio of 0.5:0.5 is layered on the hole blocking layer 9 by vacuum vapor deposition to form the cathode electrode 12. Alternatively, MgAg that is an alloy including Mg and Ag at a ratio of and Ag may be layered on the hole blocking layer 9 by vacuum vapor deposition to form the cathode electrode 12. A film thickness of the cathode electrode 12 can be, for example, 10 to 50 nm.

In the light-emitting device 100 having the configuration described above, holes (arrow h⁺ in FIG. 1) injected from the anode electrode 4 are transported to the light-emitting layer 8 via the hole injection layer 5, the hole transport layer 6, and the electron blocking layer 7. Further, electrons (arrow e⁻ in FIG. 1) injected from the cathode electrode 12 are transported to the light-emitting layer 8 via the electron injection layer 11, the electron transport layer 10, and the hole blocking layer 9. The hole and the electron transported to the light-emitting layer 8 recombine to generate an exciton. Then, the exciton returns from an excited state to a ground state, and thus light is emitted.

Note that, in the light-emitting device 100 according to the embodiment of the disclosure, as illustrated in FIG. 1, a top-emitting configuration in which light emitted from the light-emitting layer 8 is extracted from an opposite side to the array substrate 2 (upward direction in FIG. 1) is exemplified.

### Energy Relationship of Light-Emitting Element

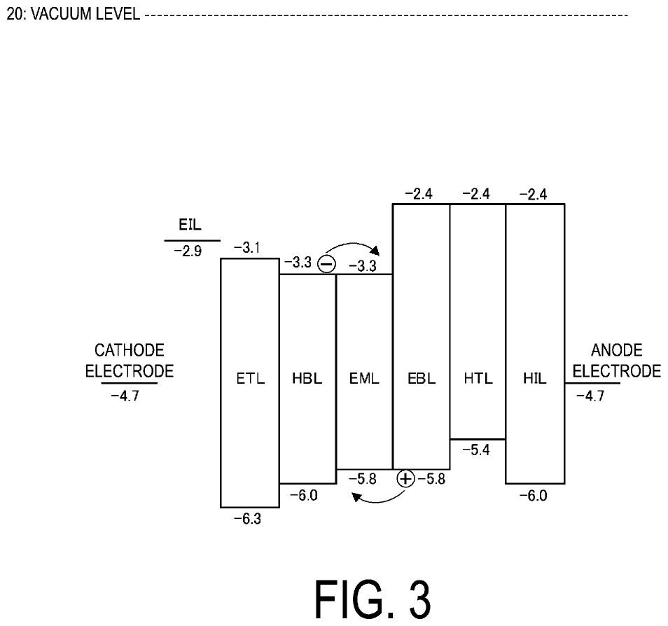

Next, with reference to FIG. 3, a relationship of energy between layers constituting the light-emitting element 3 having the configuration described above will be described. FIG. 3 is an energy diagram illustrating a relationship between a lowest unoccupied molecular orbital (LUMO) and a highest occupied molecular orbital (HOMO) in each layer of the light-emitting element 3 according to the embodiment of the disclosure. FIG. 3 illustrates a state where no voltage is applied from the outside and each layer included in the light-emitting element 3 is isolated.

Note that, as illustrated in FIG. 3, the cathode electrode 12, the electron injection layer 11, the electron transport layer 10, the hole blocking layer 9, the light-emitting layer 8, the electron blocking layer 7, the hole transport layer 6, the hole injection layer and the anode electrode 4 are arranged from left to right in the drawing. In the specification, the electron injection layer 11, the electron transport layer 10, the hole blocking layer 9, the light-emitting layer 8, the electron blocking layer 7, the hole transport layer 6, and the hole injection layer 5 are denoted as EIL, ETL, HBL, EML, EBL, HTL, and HIL, respectively, in the drawing.

In the energy diagram illustrated in FIG. 3, the anode electrode 4, the cathode electrode 12, and the electron injection layer 11 are represented by a work function. A lower end of each of the electron transport layer 10, the hole blocking layer 9, the light-emitting layer 8, the electron blocking layer 7, the hole transport layer 6, and the hole injection layer 5 corresponds to the HOMO, and indicates an ionization potential of each layer based on a vacuum level 20.

In FIG. 3, an upper end of each of the electron transport layer 10, the hole blocking layer 9, the light-emitting layer 8, the electron blocking layer 7, the hole transport layer 6, and the hole injection layer 5 corresponds to the LUMO, and indicates an electron affinity of each layer based on the vacuum level 20. In the following description, both the ionization potential and the electron affinity are assumed to be based on the vacuum level 20 when the ionization potential or the electron affinity is described simply.

In the light-emitting element 3 according to the embodiment, as described above, the light-emitting layer 8 includes a material having a perovskite structure. Thus, the light-emitting layer 8 has a narrow full width at half maximum (FWHM) of a peak wavelength of an electroluminescence (EL) spectrum, and can emit light having deeper chromaticity than a light-emitting layer including an organic light-emitting material used in a general OLED.

In the light-emitting layer 8 including a material having a perovskite structure, a crystal itself of a semiconductor constituting the light-emitting layer 8 emits light, and thus insulating properties increase and charge transport properties decrease. Further, charges that do not consume energy in the light-emitting layer 8 pass through the light-emitting layer 8 as they are and leak from the light-emitting layer 8.

Thus, when a material having a perovskite structure is used as a light-emitting material in the light-emitting layer 8, it is necessary to adjust charge injection into the light-emitting layer 8 to achieve carrier balancing in the light-emitting layer 8, and to confine charges in the light-emitting layer 8 to improve a recombination probability of electrons and holes.

Thus, in the light-emitting element 3 according to the embodiment, the electron blocking layer 7 and the hole blocking layer 9 are provided so as to sandwich the light-emitting layer 8, and the electron blocking layer 7 and the hole blocking layer 9 are configured to have an effect of confining charges in the light-emitting layer 8.

In other words, as illustrated in FIG. 3, a value of the LUMO of the light-emitting layer 8 is −3.3, and a value of the LUMO of the electron blocking layer 7 provided adjacent to an anode electrode-side main surface of the light-emitting layer 8 is −2.4. In this way, a value of the LUMO of the electron blocking layer 7 is greater than that of the light-emitting layer 8. In other words, the electron blocking layer 7 having an electron affinity less than that of the light-emitting layer 8 is provided adjacent to the anode electrode-side main surface of the light-emitting layer 8. Thus, the electron blocking layer 7 can suppress migration, from the light-emitting layer 8 to the anode electrode 4 side, of electrons (indicated by (−) in FIG. 3) injected into the light-emitting layer 8.

On the other hand, a value of the HOMO of the light-emitting layer 8 is −5.8, and a value of the HOMO of the hole blocking layer 9 provided adjacent to a main surface of the light-emitting layer 8 on the cathode electrode 12 side is −6.0. In this way, a value of the HOMO of the hole blocking layer 9 is less than that of the light-emitting layer 8. In other words, the hole blocking layer 9 having an ionization potential greater than that of the light-emitting layer 8 is provided adjacent to the cathode electrode-side main surface of the light-emitting layer 8. Thus, the hole blocking layer 9 can suppress migration, from the light-emitting layer 8 to the cathode electrode 12 side, of holes (indicated by (+) in FIG. 3) injected into the light-emitting layer 8.

Thus, in the light-emitting element 3 according to the embodiment, the recombination probability can be improved by confining holes and electrons in the light-emitting layer 8. Therefore, the light-emitting element 3 according to the embodiment can improve the lifetime of the light-emitting layer 8.

Note that, in the above description, the configuration of the light-emitting element 3 including the light-emitting layer 8 including CsPbBr₃, the electron blocking layer 7 including PCPPn, and the hole blocking layer 9 including CBP/CsCO₃ is described as an example. However, the light-emitting element 3 is not limited to this configuration as long as the recombination probability can be improved by confining electrons and holes in the light-emitting layer 8 as described above.

For example, when the light-emitting layer 8 includes Cl as a material having a perovskite structure, the electron blocking layer 7 may include PCPPn and a p-type semiconductor material such as MoO₃ or V₂O₅, and the hole blocking layer 9 may include CBP and an n-type semiconductor material such as ZnO, SiO, and TiO₂.

Further, the light-emitting element 3 according to the embodiment described above has the configuration in which the electron blocking layer 7 and the hole blocking layer 9 are provided in the positions adjacent to the light-emitting layer 8. However, the light-emitting element 3 does not necessarily need to include both of the electron blocking layer 7 and the hole blocking layer 9, and may be configured to include only one of the electron blocking layer 7 and the hole blocking layer 9 as long as an effect of confining charges is obtained in the light-emitting layer 8.

### Viewing Angle Characteristic of Light-Emitting Device

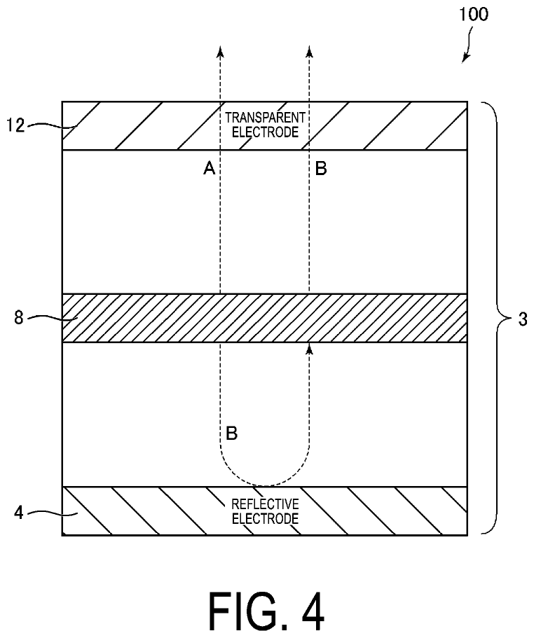

Next, a viewing angle characteristic of the light-emitting device 100 according to the embodiment will be described with reference to FIG. 4. FIG. 4 is a diagram schematically illustrating an example of a path of light emitted from the light-emitting element 3 included in the light-emitting device 100 according to the embodiment of the disclosure.

As illustrated in FIG. 4, in the light-emitting element 3 according to the embodiment, the first electrode located in the lower layer (the anode electrode 4 located on the array substrate 2 side) is a reflective electrode, and the second electrode located in the upper layer (the cathode electrode 12 located on a side opposite to the array substrate 2) is a transparent electrode. Then, the light-emitting element 3 has a top-emitting configuration in which light is extracted from a light extraction surface (not illustrated) provided above the light-emitting element 3. In such a configuration, light emitted from the light-emitting layer 8 has a path A directly traveling toward the light extraction surface and a path B reflected by the first electrode (anode electrode 4) and traveling toward the light extraction surface, and an optical distance of the path B is longer than that of the path A by a round-trip distance between the light-emitting layer 8 and the anode electrode 4. In particular, the light-emitting element 3 according to the embodiment has a configuration in which the hole transport layer 6 and the hole injection layer 5 having a film thickness thicker than that of the electron transport layer 10 and the electron injection layer 11 are disposed between the light-emitting layer 8 and the first electrode (anode electrode 4). Thus, a distance between the light-emitting layer 8 and the first electrode (anode electrode 4) increases. When the optical distance between the light-emitting layer 8 and the first electrode (anode electrode 4) is a half wavelength of a wavelength (λ) of the light emitted from the light-emitting layer 8, the extracted light is strongly subjected to optical interference. Thus, it is necessary to optimize a film thickness of each layer included in the light-emitting element 3.

Thus, the light-emitting element 3 according to the embodiment is configured to have a layered structure in which an optical distance from the anode electrode 4 to the light-emitting layer 8 satisfies the relationship of 1/2×λ×n (n is an odd number), where a wavelength of the light emitted from the light-emitting layer 8 is λ. Note that it is particularly preferable that n is 3. By adjusting a film thickness of the electron blocking layer 7, the light-emitting element 3 can have a layered body structure having an optical distance that satisfies the relationship described above.

In this way, since the light-emitting element 3 has a layered structure in which an optical distance from the first electrode (cathode electrode 12) to the light-emitting layer 8 satisfies the relationship described above, the light directly extracted from the light-emitting layer 8 and the light reflected by the anode electrode 4 and extracted are in the same phase, and the two light beams have a relationship in which they intensify each other by interference. Thus, a waveform of the peak wavelength of the EL spectrum becomes steeper and more conspicuous. In other words, only light of a desired wavelength can be emphasized. Thus, the viewing angle characteristic of the light-emitting device 100 can be improved.

Note that the viewing angle characteristic is a chromaticity shift, a change in luminance, or the like between when a display surface is viewed from the front of the light-emitting device 100 (a direction perpendicular to the display surface of the light-emitting device 100) and when the display surface is viewed from a direction inclined at a certain angle from the front.

### Evaluation Experiment on Viewing Angle Characteristic

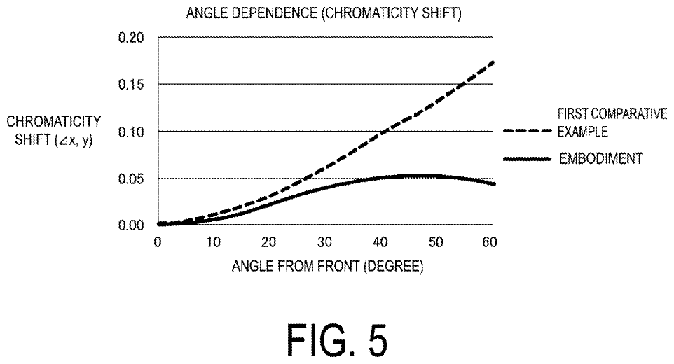

Here, the light-emitting device 100 according to the embodiment described above and a light-emitting device according to a first comparative example including a light-emitting element including an organic light-emitting material used in a general OLED were prepared. Angle dependence related to a chromaticity shift between the two was simulated by using SETFOS manufactured by Cyber Net Inc. As a result, a graph shown in FIG. 5 was obtained. FIG. 5 is a graph showing the angle dependence related to the chromaticity shift between the light-emitting device 100 according to the embodiment of the disclosure and the light-emitting device according to the first comparative example. In FIG. 5, the horizontal axis represents an angle from the front, and the vertical axis represents a chromaticity shift (Δx, y).

Note that the angle from the front indicates an inclination from a reference (0 degree) which is a direction perpendicular to the display surface of the light-emitting device 100. The chromaticity shift (Δx, y) indicates a difference between chromaticity when the display surface is viewed from the front and chromaticity when the display surface is viewed from a position inclined from the reference. Specifically, the chromaticity shift (Δx, y) is represented by a Euclidean distance between two colors represented by color coordinates (x, y) in the CIE color system.

The light-emitting element included in the light-emitting device according to first comparative example had a layered structure similar to that of the light-emitting element 3 according to the first embodiment, and a tricoordinate iridium complex (Ir(ppy)₃) was used as an organic light-emitting layer material forming a light-emitting layer. Note that each layer constituting the light-emitting element included in the light-emitting device according to the first comparative example has a configuration similar to that of each layer of the light-emitting element 3 according to the first embodiment except for the light-emitting layer.

As shown in FIG. 5, for example, when the angle from the front is 40 degrees, the chromaticity shift (Δx, y) is 0.051 in the light-emitting device 100 according to the first embodiment, whereas the chromaticity shift (Δx, y) is 0.100 in the light-emitting device according to the first comparative example. In this way, it was found that the chromaticity shift of the light-emitting device 100 according to the first embodiment was reduced by half as compared with the light-emitting device according to the first comparative example.

Further, there was no significant difference in luminance between the light-emitting device 100 according to the first embodiment and the light-emitting device according to the first comparative example. On the other hand, the chromaticity of the light-emitting device 100 in the CIE color system (x, y) was (0.13, 0.81), and the chromaticity of the light-emitting device according to the first comparative example in the CIE color system (x, y) was (0.20, 0.79). From this result, it was found that the color purity of the light-emitting device 100 was higher than that of the light-emitting device according to the first comparative example.

### First Modified Example

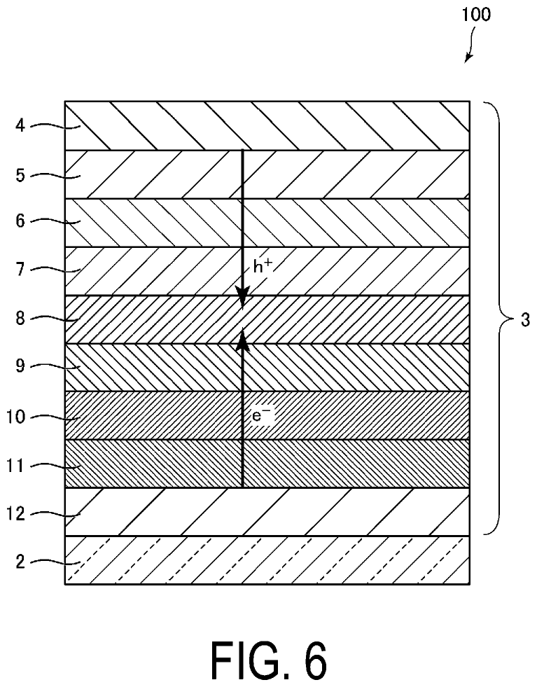

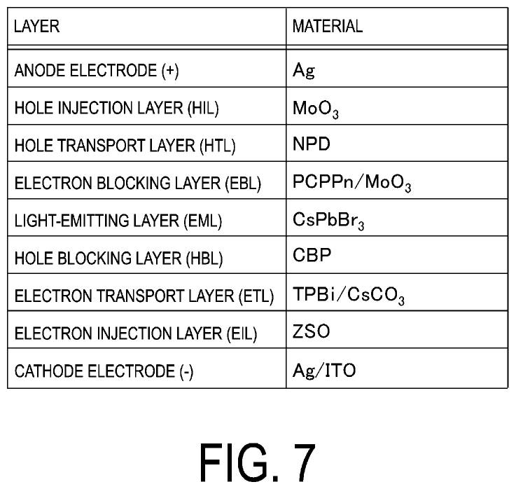

Next, the light-emitting device 100 according to a first modified example of the embodiment of the disclosure will be described with reference to FIGS. 6 and 7. FIG. 6 is a schematic cross-sectional view of the light-emitting device 100 according to the first modified example of the embodiment of the disclosure. In FIG. 6, a direction from the array substrate 2 of the light-emitting device 100 toward the light-emitting element 3 may be described as an “upward direction”, and an opposite direction may be described as a “downward direction”. FIG. 7 is a table showing a correspondence relationship between each layer constituting the light-emitting element 3 included in the light-emitting device 100 illustrated in FIG. 6, and a material forming each layer.

The light-emitting device 100 according to the embodiment has a configuration in which the anode electrode 4 is disposed in the lower layer and the cathode electrode 12 is disposed in the upper layer. In contrast, the light-emitting device 100 according to the first modified example of the embodiment has a configuration in which the cathode electrode 12 is disposed in the lower layer and the anode electrode 4 is disposed in the upper layer. In other words, a layering order of the layers is reversed between the light-emitting device 100 according to the embodiment and the light-emitting device 100 according to the first modified example of the embodiment.

Further, a material constituting each layer is changed by reversing the layering order of each layer. In particular, the light-emitting device 100 according to the first modified example is significantly different from the light-emitting element 3 according to the embodiment in a point that an inorganic material is used as a material constituting the electron injection layer 11.

Specifically, the light-emitting element 3 included in the light-emitting device 100 according to the first modified example of the embodiment has a configuration in which the cathode electrode 12 (first electrode), the electron injection layer 11, the electron transport layer 10, the hole blocking layer 9, the light-emitting layer 8, the electron blocking layer 7, the hole transport layer 6, the hole injection layer 5, and the anode electrode 4 (second electrode) are layered in this order from the bottom.

The light-emitting element 3 according to the first modified example of the embodiment can be manufactured as follows. First, as shown in FIG. 7, the cathode electrode 12 is formed of a layered body of Ag and ITO. In other words, Ag is layered as a reflective layer on the array substrate 2 by sputtering. A thickness of the reflective layer film-formed on the array substrate 2 can be, for example, 100 nm. Subsequently, a transparent electrode (ITO) is continuously layered. A thickness of the transparent electrode layered herein can be, for example, 20 nm. The layered body of Ag/ITO formed in such a manner is processed into a desired pattern by, for example, photolithography to form the cathode electrode 12.

Next, as shown in FIG. 7, the electron injection layer 11 is formed of amorphous Zn—Si—O (ZSO) in which ZnO is doped with SiO. A composition ratio of Si in the ZSO is a value such that a proportion of Zn in Zn+Si is in a range of 75% or more and 80% or less.

The electron injection layer 11 is formed by depositing a ZSO layer having a film thickness of 100 nm on the cathode electrode 12 by sputter deposition. Although a configuration in which ZSO is used as a material for forming the electron injection layer 11 has been described, for example, (CaO)₁₂(Al₂O₃)₇ or an oxide such as BaO having a work function around −3 eV may be used as a material for forming the electron injection layer 11.

Next, as shown in FIG. 7, the electron transport layer 10 is formed by co-evaporating 1,3,5-tris (1-phenyl-1H-benzimidazol-2-yl) benzene (TPBi) and CsCO₃ on the electron injection layer 11.

Subsequently, CBP is deposited on the electron transport layer 10 to form the hole blocking layer 9 having a film thickness of 10 nm. Note that, before the hole blocking layer 9 is formed, surface treatment may be performed by Ar plasma in order to activate the surface of the oxide of the electron transport layer 10 located below the hole blocking layer 9.

Note that a film thickness of the hole blocking layer 9 may be appropriately adjusted such that an optical distance in which the light emitted from the light-emitting layer 8 of the light-emitting element 3 according to the first modified example moves has a layered structure that satisfies the above-described condition (1/2×λ×n (n is an odd number)).

After the hole blocking layer 9 is formed as described above, the light-emitting layer 8 is formed on the hole blocking layer 9. A method for forming the light-emitting layer 8 is similar to that of the light-emitting layer 8 included in the light-emitting element 3 according to the embodiment described above, and thus description thereof will be omitted.

After the light-emitting layer 8 is formed, PCPPn and MoO₃ are co-evaporated in vacuum on the light-emitting layer 8 to form the electron blocking layer 7 having a film thickness of 10 nm.

After the electron blocking layer 7 is formed, NPD is deposited on the electron blocking layer 7 to form the hole transport layer 6 having a film thickness of 20 nm.

After the hole transport layer 6 is formed, MoO₃ is deposited on the hole transport layer 6 to form the hole injection layer 5 having a film thickness of 5 nm.

After the hole injection layer 5 is formed, Ag is deposited on the hole injection layer 5 to form the anode electrode 4 having a film thickness of 20 nm.

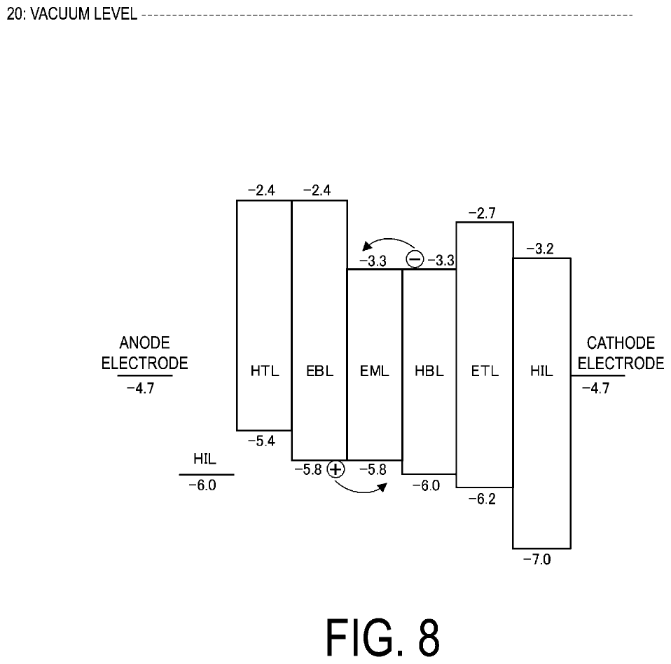

FIG. 8 illustrates a relationship of energy between layers constituting the light-emitting element 3 according to the first modified example having the configuration described above. FIG. 8 is an energy diagram illustrating a relationship between a lowest unoccupied molecular orbital (LUMO) and a highest occupied molecular orbital (HOMO) in each layer of the light-emitting element 3 according to the first modified example of the embodiment of the disclosure. FIG. 8 illustrates a state where no voltage is applied from the outside and each layer included in the light-emitting element 3 is isolated.

As illustrated in FIG. 8, a value of the LUMO of the light-emitting layer 8 is −3.3, and a value of the LUMO of the electron blocking layer 7 provided adjacent to an anode electrode-side main surface of the light-emitting layer 8 is −2.4. In this way, a value of the LUMO of the electron blocking layer 7 is greater than that of the light-emitting layer 8. In other words, the electron blocking layer 7 having an electron affinity less than that of the light-emitting layer 8 is provided adjacent to the anode electrode-side main surface of the light-emitting layer 8. Thus, the electron blocking layer 7 suppresses migration from the light-emitting layer 8 to the anode electrode 4 side of electrons (indicated by (−) in FIG. 8) injected into the light-emitting layer 8.

On the other hand, a value of the HOMO of the light-emitting layer 8 is −5.8, and a value of the HOMO of the hole blocking layer 9 provided adjacent to a main surface of the light-emitting layer 8 on the cathode electrode 12 side is −6.0. In this way, a value of the HOMO of the hole blocking layer 9 is less than that of the light-emitting layer 8. In other words, the hole blocking layer 9 having an ionization potential greater than that of the light-emitting layer 8 is provided adjacent to the cathode electrode-side main surface of the light-emitting layer 8. Thus, the hole blocking layer 9 suppresses migration from the light-emitting layer 8 to the cathode electrode 12 side of holes (indicated by (+) in FIG. 8) injected into the light-emitting layer 8.

Thus, in the light-emitting element 3 according to the first modified example of the embodiment, the recombination probability can be improved by confining holes and electrons in the light-emitting layer 8. Therefore, the light-emitting element 3 according to the first modified example of the embodiment can improve the lifetime of the light-emitting layer 8.

Further, the light-emitting element 3 according to the first modified example of the embodiment described above has the configuration in which the electron blocking layer 7 and the hole blocking layer 9 are provided in the positions adjacent to the light-emitting layer 8. However, the light-emitting element 3 does not necessarily need to include both of the electron blocking layer 7 and the hole blocking layer 9, and may be configured to include only one of the electron blocking layer 7 and the hole blocking layer 9 as long as an effect of confining charges is obtained in the light-emitting layer 8.

For example, in a case of a configuration in which the electron transport layer 10 is formed of an inorganic material such as ZSO, the electron transport layer 10 can function as the hole blocking layer 9, and thus a configuration in which only the electron blocking layer 7 is provided and the hole blocking layer 9 is not provided may be employed.

In the light-emitting element 3 according to the first modified example of the embodiment, the first electrode located in the lower layer (the cathode electrode 12 located on the array substrate 2 side) is a reflective electrode, and the second electrode located in the upper layer (the anode electrode 4 located on a side opposite to the array substrate 2) is a transparent electrode. Then, the light-emitting element 3 has a top-emitting configuration in which light is extracted from a light extraction surface (not illustrated) provided above the light-emitting element 3.

Thus, similarly to the light-emitting element 3 according to the embodiment, the light-emitting element 3 according to the first modified example of the embodiment is configured to have a layered structure in which an optical distance from the first electrode (cathode electrode 12) to the light-emitting layer 8 satisfies the relationship of 1/2×λ×n (n is an odd number), where a wavelength of the light emitted from the light-emitting layer 8 is λ. Note that it is particularly preferable that n is 3. By adjusting a film thickness of the hole blocking layer 9, the light-emitting element 3 according to the first modified example may achieve a layered body structure having an optical distance that satisfies the relationship described above.

In this way, since the light-emitting element 3 according to the first modified example has a layered structure in which an optical distance from the first electrode (cathode electrode 12) to the light-emitting layer 8 satisfies the relationship described above, the light directly extracted from the light-emitting layer 8 and the light reflected by the anode electrode 4 and extracted are in the same phase, and the two light beams have a relationship in which they intensify each other by interference. Thus, the viewing angle characteristic of the light-emitting device 100 can be improved.

### Evaluation Experiment on Viewing Angle Characteristic

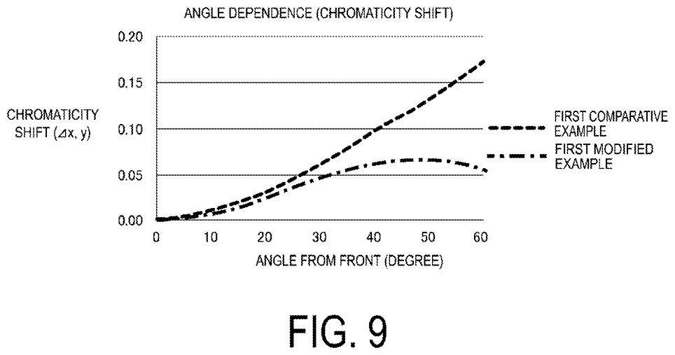

An evaluation experiment on a viewing angle characteristic is also performed on the light-emitting device 100 according to the first modified example of the embodiment similarly to the light-emitting device according to the embodiment. As a result, a graph shown in FIG. 9 was obtained. FIG. 9 is a graph showing angle dependence related to a chromaticity shift between the light-emitting device 100 according to the first modified example of the embodiment of the disclosure and the light-emitting device according to the first comparative example. In FIG. 9, the horizontal axis represents an angle from the front, and the vertical axis represents a chromaticity shift (Δx, y). Note that a technique of the evaluation experiment is similar to the technique performed on the optical device 100 according to the embodiment, and thus description thereof will be omitted.

As shown in FIG. 9, for example, when the angle from the front is 40 degrees, the chromaticity shift (Δx, y) is 0.060 in the light-emitting device 100 according to the first modified example, whereas the chromaticity shift (Δx, y) is 0.100 in the light-emitting device according to the first comparative example. In this way, it was found that the chromaticity shift of the light-emitting device 100 according to the first modified example was reduced by half as compared with the light-emitting device according to the first comparative example.

Further, there was no significant difference in luminance between the light-emitting device 100 according to the first modified example and the light-emitting device according to the first comparative example. On the other hand, the chromaticity of the light-emitting device 100 in the CIE color system (x, y) was (0.12, 0.81), and the chromaticity of the light-emitting device according to the first comparative example in the CIE color system (x, y) was (0.20, 0.79). From this result, it was found that the color purity of the light-emitting device 100 was higher than that of the light-emitting device according to the first comparative example.

### Second Modified Example

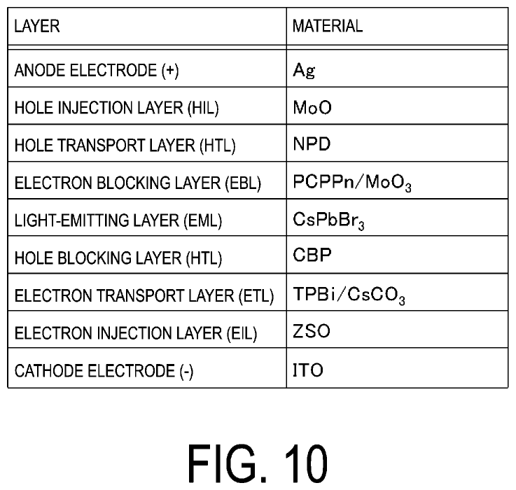

Next, the light-emitting device 100 according to a second modified example of the embodiment of the disclosure will be described with reference to FIG. 10. FIG. 10 is a table showing a correspondence relationship between each layer constituting the light-emitting element 3 included in the light-emitting device 100 according to the second modified example of the embodiment of the disclosure, and a material forming each layer.

The light-emitting element 3 included in the light-emitting device 100 according to the second modified example has a configuration substantially similar to that of the light-emitting element 3 included in the light-emitting device 100 according to the first modified example. However, the light-emitting element 3 according to the second modified example is different from the light-emitting element 3 according to the first modified example in a point that the cathode electrode 12 disposed in the lower layer of the light-emitting element 3 according to the first modified example is a reflective electrode and the anode electrode 4 disposed in the upper layer is a transparent electrode to form a top-emitting configuration, whereas the cathode electrode 12 disposed in the lower layer of the light-emitting element 3 according to the second modified example is a transparent electrode to form a bottom-emitting configuration.

Thus, as shown in FIG. 10, the light-emitting element 3 according to the second modified example is different from the light-emitting element 3 according to the first modified example in a point that the cathode electrode 12 in the light-emitting element 3 according to the first modified example is formed of an Ag/ITO layered body, whereas the cathode electrode 12 in the light-emitting element 3 according to the second modified example is formed of ITO. In this way, in the light-emitting element 3 according to the second modified example, each layer is formed of a material similar to that of the light-emitting element 3 according to the first modified example except that a material forming the cathode electrode 12 is changed, and thus a method for manufacturing each layer will be omitted.

Further, since each layer of the light-emitting element 3 according to the second modified example is formed of a material similar to that of each layer of the light-emitting element 3 according to the first modified example except for the cathode electrode 12 as described above, an energy relationship of each layer is also similar. Thus, similarly to the light-emitting element 3 according to the first modified example, in the light-emitting element 3 according to the second modified example, the recombination probability can be improved by confining holes and electrons in the light-emitting layer 8. Therefore, the light-emitting element 3 according to the second modified example of the embodiment can improve the lifetime of the light-emitting layer 8.

### Evaluation Experiment on Viewing Angle Characteristic

An evaluation experiment on a viewing angle characteristic related to a chromaticity shift is also performed on the light-emitting device 100 according to the second modified example of the embodiment similarly to the light-emitting device according to the embodiment. The light-emitting device 100 according to the second modified example, the light-emitting device according to the first comparative example described above, and a light-emitting device according to a second comparative example were prepared. The light-emitting device according to the second comparative example is obtained by changing the configuration of the light-emitting device according to the first comparative example from the top-emitting configuration to the bottom-emitting configuration. A technique of the evaluation experiment is similar to the technique performed on the optical device 100 according to the embodiment and the optical device 100 according to the first modified example of the embodiment, and thus description thereof will be omitted.

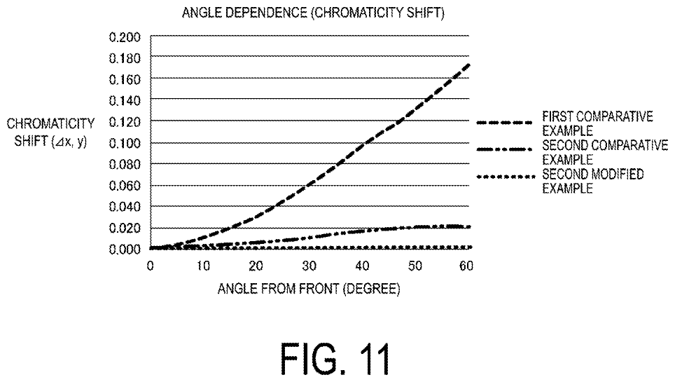

The results shown in FIG. 11 were obtained by this evaluation experiment. FIG. 11 is a graph showing angle dependence related to a chromaticity shift among the light-emitting device 100 according to the second modified example of the embodiment of the disclosure, the light-emitting device according to the first comparative example, and the light-emitting device according to the second comparative example. In FIG. 11, the horizontal axis represents an angle from the front, and the vertical axis represents a chromaticity shift (Δx, y).

As shown in FIG. 11, when the light-emitting device according to the first comparative example having a top-emitting light-emitting element was compared with the light-emitting device according to the second comparative example having a bottom-emitting light-emitting element, it was found that the light-emitting device according to the first comparative example had a greater chromaticity shift in accordance with the angle from the front. In particular, it was found that a difference in the magnitude of the chromaticity shift significantly increased as the angle from the front increased. The conceivable reason is that optical interference hardly occurs in the bottom-emitting light-emitting element unlike the top-emitting light-emitting element.

Next, the light-emitting device 100 according to the second modified example of the embodiment and the light-emitting device according to the second comparative example are compared. Since both of the light-emitting devices have a configuration including a bottom-emitting light-emitting element, a chromaticity shift hardly occurs even when the angle from the front becomes greater. However, it was found that the light-emitting device 100 according to the second modified example of the embodiment had a less chromaticity shift than that of the light-emitting device according to the second comparative example. Thus, it was found that the angle dependence related to the chromaticity shift could be further improved by forming the light-emitting layer 8 of the light-emitting element 3 by using a material having a perovskite structure.

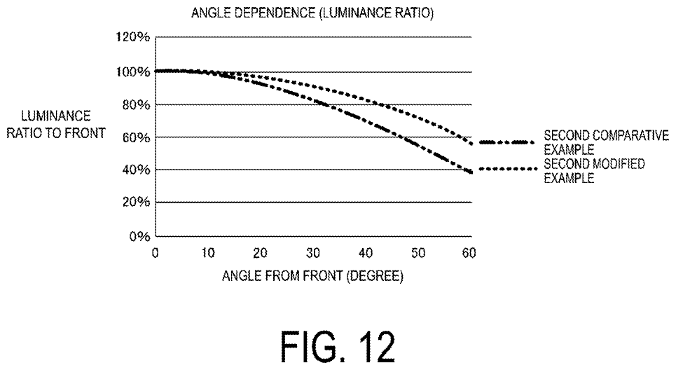

Next, the angle dependence related to luminance between the light-emitting device 100 according to the second modified example of the embodiment described above and the light-emitting device according to the second comparative example was simulated by using SETFOS manufactured by Cyber Net Inc. As a result, a graph shown in FIG. 12 was obtained. FIG. 12 is a graph showing angle dependence related to luminance between the light-emitting device 100 according to the second modified example of the embodiment of the disclosure and the light-emitting device according to the second comparative example. In FIG. 12, the horizontal axis represents an angle from the front, and the vertical axis represents a luminance ratio (%) to the front. Note that the luminance ratio to the front indicates a ratio of a luminance value when the display surface of the light-emitting device is viewed from the front to a luminance value when the display surface is viewed from a direction inclined at a certain angle from the front.

As shown in FIG. 12, in both of the light-emitting device 100 according to the second modified example of the embodiment and the light-emitting device according to the second comparative example, it was found that a luminance value decreased as an inclination from the front increased. For example, when the angle from the front was 60 degrees, the luminance ratio of the light-emitting device 100 according to the second modified example of the embodiment to the front was 55%, and the luminance ratio of the light-emitting device according to the second comparative example to the front was 38%. However, it was found that the light-emitting device 100 according to the second modified example of the embodiment was less likely to decrease in luminance than the light-emitting device according to the second comparative example.

Further, the chromaticity of the light-emitting device 100 according to the second modified example of the embodiment in the CIE color system (x, y) was (0.12, 0.81), and the chromaticity of the light-emitting device according to the second comparative example in the CIE color system (x, y) was (0.27, 0.67). From this result, it was found that the color purity of the light-emitting device 100 according to the second modified example of the embodiment was higher than that of the light-emitting device according to the second comparative example.

As described above, it was found that the light-emitting element 3 according to second modified example was more improved in chromaticity shift, luminance decrease, and color purity than the light-emitting element according to the second comparative example.

Note that the elements described in the above-described embodiments and the modified examples may be appropriately combined in a range in which a contradiction does not arise.

### REFERENCE SIGNS LIST

3 Light-emitting element
4 Anode electrode
5 Hole injection layer
6 Hole transport layer
7 Electron blocking layer
8 Light-emitting layer
9 Hole blocking layer
10 Electron transport layer
11 Electron injection layer
12 Cathode electrode
20 Vacuum level
100 Light-emitting device

1. A light-emitting element comprising:
a first electrode;
a second electrode;
a light-emitting layer provided between the first electrode and the second electrode and including a material having a perovskite structure; and
a blocking layer provided in at least one of a position between the first electrode and the light-emitting layer or a position between the second electrode and the light-emitting layer, and configured to suppress migration of charges from the light-emitting layer.

2. The light-emitting element according to claim 1,
wherein the material having the perovskite structure is a lead metal halide compound.

3. The light-emitting element according to claim 2,
wherein the lead metal halide compound is represented by MPbX₃ (M;Cs, MeNH₃, X;I, Br, Cl).

4. The light-emitting element according to claim 1,
wherein the first electrode is an anode electrode and the second electrode is a cathode electrode,
the blocking layer is an electron blocking layer provided between the first electrode and the light-emitting layer and configured to suppress migration of electrons from the light-emitting layer, and
the electron blocking layer includes 3-[4-(9-phenanthryl)-phenyl]-9-phenyl-9H-carbazole.

5. The light-emitting element according to claim 4,
wherein the electron blocking layer includes a p-type semiconductor material.

6. The light-emitting element according to claim 5,
wherein the p-type semiconductor material is MoO₃ or V₂O₅.

7. The light-emitting element according to claim 1,
wherein the first electrode is an anode electrode and the second electrode is a cathode electrode,
the blocking layer is an electron blocking layer provided between the first electrode and the light-emitting layer and configured to suppress migration of electrons from the light-emitting layer, and
an electron affinity of the electron blocking layer is less than an electron affinity of the light-emitting layer.

8. The light-emitting element according to claim 1,
wherein the first electrode is an anode electrode and the second electrode is a cathode electrode,
the blocking layer is a hole blocking layer provided between the second electrode and the light-emitting layer and configured to suppress migration of holes from the light-emitting layer, and
the hole blocking layer includes 4,4′-bis(N-carbazolyl)-1,1′-biphenyl.

9. The light-emitting element according to claim 8,
wherein the hole blocking layer includes an n-type semiconductor material.

10. The light-emitting element according to claim 9,
wherein the n-type semiconductor material includes at least one type selected from a group of CsCO₃, ZnO, and TiO₂.

11. The light-emitting element according to claim 1,
wherein the first electrode is an anode electrode and the second electrode is a cathode electrode,
the blocking layer is a hole blocking layer provided between the second electrode and the light-emitting layer and configured to suppress migration of holes from the light-emitting layer, and
an ionization potential of the hole blocking layer is greater than an ionization potential of the light-emitting layer.

12. The light-emitting element according to claim 1,
wherein the first electrode is a reflective electrode configured to reflect light emitted from the light-emitting layer,
the second electrode is a transparent electrode configured to transmit light emitted from the light-emitting layer and light reflected by the first electrode, and
an optical distance from the first electrode to the light-emitting layer satisfies a relationship of 1/2×λ×n (n is an odd number), where a wavelength of light emitted from the light-emitting layer is λ.

13. The light-emitting element according to claim 1,
wherein the light-emitting element has a layered structure in which the first electrode is located below the light-emitting layer and the second electrode is located above the light-emitting layer, and
the second electrode is a transparent electrode configured to transmit light emitted from the light-emitting layer.

14. The light-emitting element according to claim 1,
wherein the light-emitting element has a layered structure in which the first electrode is located below the light-emitting layer and the second electrode is located above the light-emitting layer, and
the first electrode is a transparent electrode configured to transmit light emitted from the light-emitting layer.

15. A light-emitting device comprising:
a thin film transistor; and
the light-emitting element according to claim 1 electrically connected to the thin film transistor.
